(19) United States
(12) Patent Application Publication
(10) Pub. No.: US 2025/0028006 A1
(43) Pub. Date: Jan. 23, 2025

(54) DEGRADATION STATE ESTIMATION SYSTEM, DEGRADATION STATE ESTIMATION METHOD, AND NON-TRANSITORY COMPUTER-READABLE RECORDING MEDIUM

(71) Applicant: Panasonic Intellectual Property Management Co., Ltd., Osaka (JP)

(72) Inventors: Changhui YANG, Osaka (JP); Takashi MATSUDA, Osaka (JP)

(21) Appl. No.: 18/710,146

(22) PCT Filed: Nov. 15, 2022
(86) PCT No.: PCT/JP2022/042370

§ 371 Date: May 14, 2024

(30) Foreign Application Priority Data
Nov. 18, 2021 (JP) 2021-187756

(51) Int. Cl. G01R 31/392; G01R 31/374; G01R 31/3842; G01R 31/396

(52) U.S. Cl. CPC G01R 31/392; G01R 31/374; G01R 31/3842; G01R 31/396

(57) ABSTRACT

A data acquisition unit acquires usage data of a secondary battery and battery information for specifying the type of the secondary battery. A degradation characteristic search unit searches a degradation characteristic database on the basis of the battery information and specifies a degradation characteristic information that includes a storage degradation characteristic, a charging degradation characteristic, and a discharging degradation characteristic of the secondary battery. A degradation state analysis unit estimates a storage degradation amount, a charging degradation amount, and a discharging degradation amount of the secondary battery on the basis of the usage data of the secondary battery and the specified degradation characteristic information.

### CROSS-REFERENCE TO RELATED APPLICATIONS

This application is based upon and claims the benefit of priority from the prior Japanese Patent Application No. 2021-187756, filed on Nov. 18, 2021, and the International Patent Application No. PCT/JP2022/042370, filed on Nov. 15, 2022, the entire content of each of which is incorporated herein by reference.

### BACKGROUND

### Field of the Invention

The present disclosure relates to a degradation state estimation system, a degradation state estimation method, and a degradation state estimation program for estimating the degradation state of a secondary battery.

### Description of the Related Art

In general, State of Health (SOH) is used as an indicator for degradation of secondary batteries. A general method for calculating SOH is to obtain Full Charge Capacity (FCC) by dividing the integrated value of charging current by the difference between State of Charge (SOC) at the start and State of Charge (SOC) at the end of charging and then by dividing the obtained FCC by the initial FCC (see, for example, Patent Literature 1). However, the SOH based on capacity measurement may differ from the actual degradation state inside the battery and may not accurately reflect the degradation state inside the battery.

There is also a method where calculation is performed while the battery condition is divided into storage degradation and charge and discharging degradation based on a chemical reaction model inside the battery (for example, see Patent Literature 2). However, actual operation would be difficult due to a large number of parameters required to be obtained in experiments and large differences in characteristics depending on the type of battery.
Patent Literature 1: JP 2014-185896
Patent Literature 2: JP 2015-81823

### SUMMARY OF THE INVENTION

The present disclosure addresses the above-described issue, and a purpose thereof is to provide a technology that allows for highly accurate estimation of the degradation state of secondary batteries including degradation causes.

In order to solve the aforementioned problems, a degradation state estimation system according to one embodiment of the present disclosure includes: a data acquisition unit that acquires usage data of a secondary battery and battery information for specifying the type of the secondary battery; a degradation characteristic search unit that searches a degradation characteristic database on the basis of the battery information and specifies degradation characteristic information that includes a storage degradation characteristic, a charging degradation characteristic, and a discharging degradation characteristic of the secondary battery; and a degradation state analysis unit that estimates a storage degradation amount, a charging degradation amount, and a discharging degradation amount of the secondary battery on the basis of the specified degradation characteristic information and the usage data of the secondary battery. The degradation state analysis unit performs: estimating a storage degradation amount of the secondary battery on the basis of the specified storage degradation characteristic and state of charge (SOC), temperature, and elapsed time obtained based on the usage data of the secondary battery; estimating a charging degradation amount of the secondary battery on the basis of SOC, a charging rate, temperature, and a charging amount obtained based on the specified charging degradation characteristic and the usage data of the secondary battery; and estimating a discharging degradation amount of the secondary battery on the basis of SOC, a discharging rate, temperature, and a discharging amount obtained based on the specified discharging degradation characteristic and the usage data of the secondary battery.

Optional combinations of the aforementioned constituting elements and implementations of the present disclosure in the form of apparatuses, systems, methods, programs, etc., may also be practiced as additional modes of the present disclosure.

Embodiments will now be described, by way of example only, with reference to the accompanying drawings which are meant to be exemplary, not limiting, and wherein like elements are numbered alike in several Figures, in which:

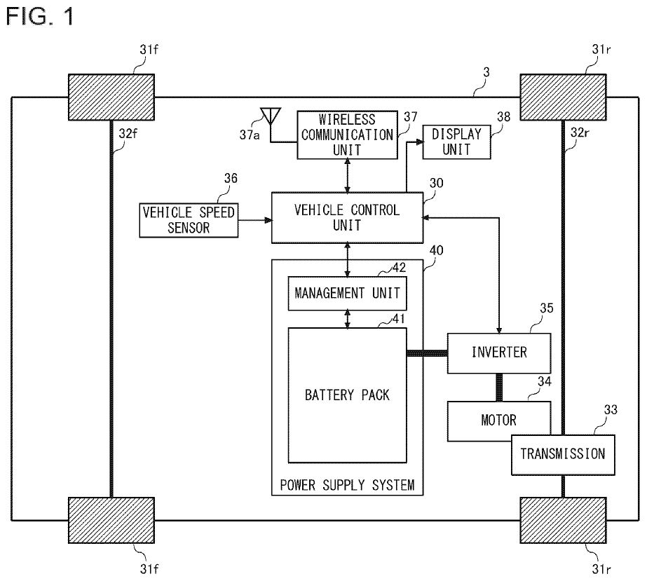

FIG. 1 is a diagram showing a schematic configuration of an electrically driven vehicle according to an embodiment.

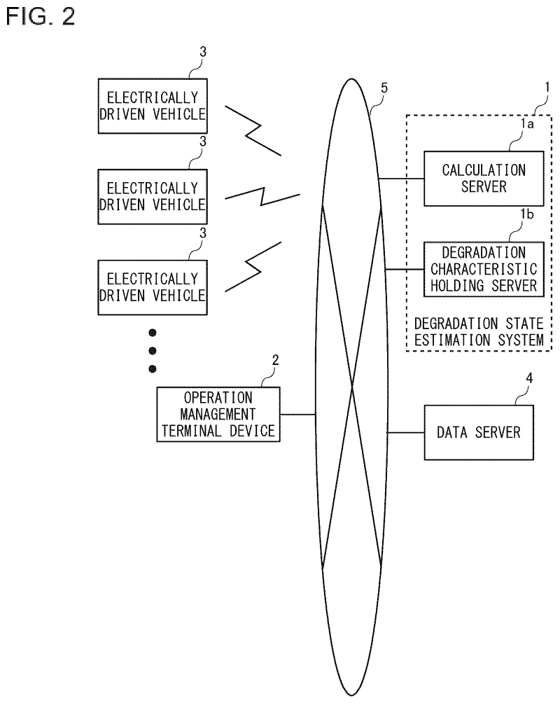

FIG. 2 is a diagram for explaining a degradation state estimation system according to the embodiment.

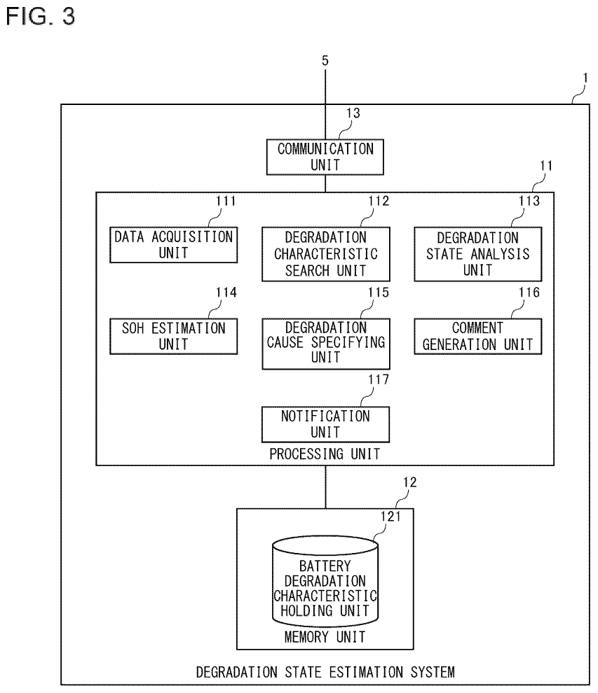

FIG. 3 is a diagram showing an example of the configuration of the degradation state estimation system according to the embodiment.

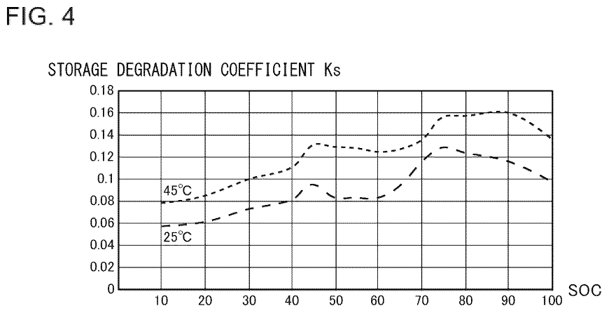

FIG. 4 is a diagram showing an example of a storage degradation characteristic map.

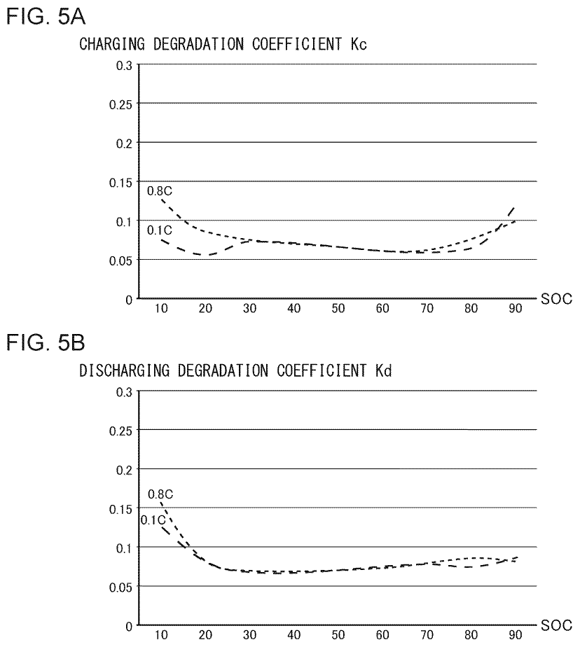

FIGS. 5A and 5B are diagrams each showing an example of a charging/discharging degradation characteristic map.

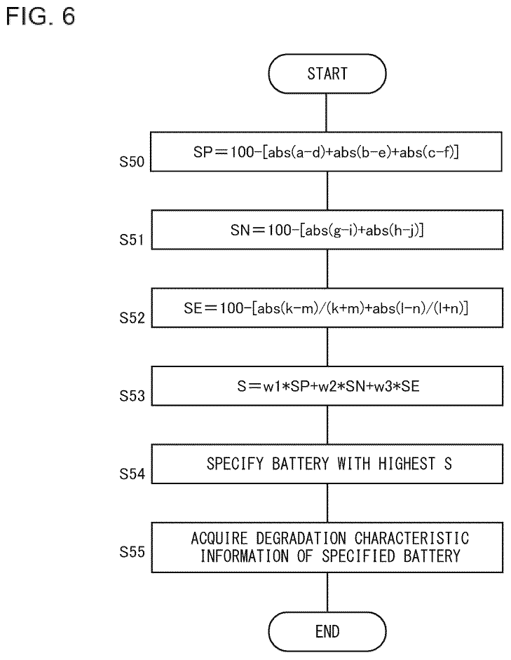

FIG. 6 is a flowchart for explaining an example of a degradation characteristic search method.

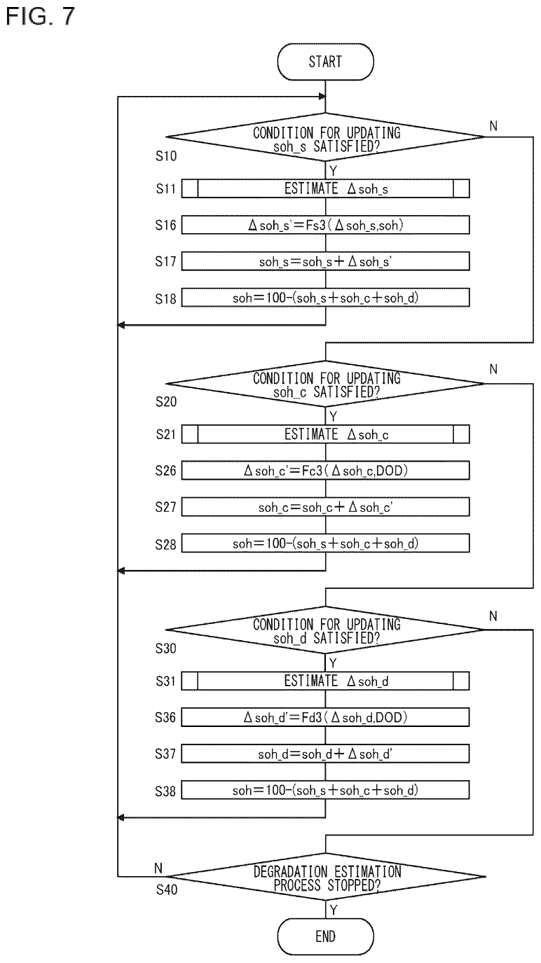

FIG. 7 is a flowchart for explaining a process of estimating SOH according to the embodiment.

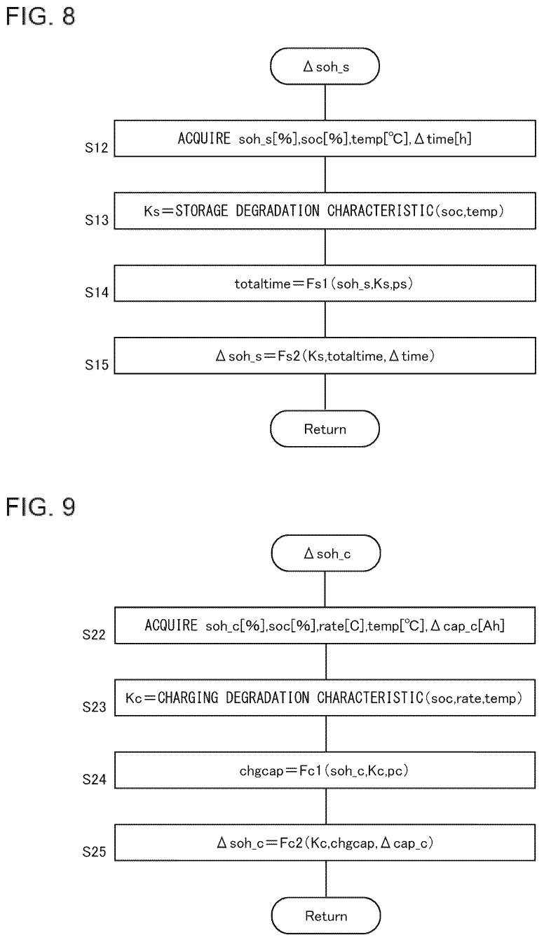

FIG. 8 is a flowchart that shows a subroutine for explaining a process of estimating a storage degradation increase amount Δsoh_s.

FIG. 9 is a flowchart that shows a subroutine for explaining a process of estimating a charging degradation increase amount Δsoh_c.

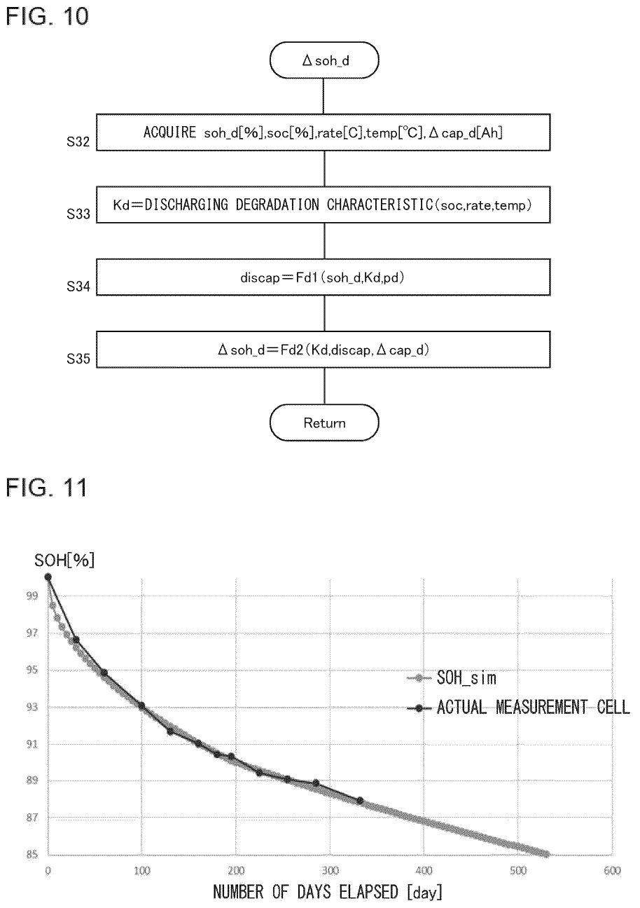

FIG. 10 is a flowchart that shows a subroutine for explaining a process of estimating a discharging degradation increase amount Δsoh_d.

FIG. 11 is a diagram that compares the transition of the SOH of a cell simulated by a degradation state estimation method according to the embodiment and the transition of the SOH of a cell based on actual measurement results.

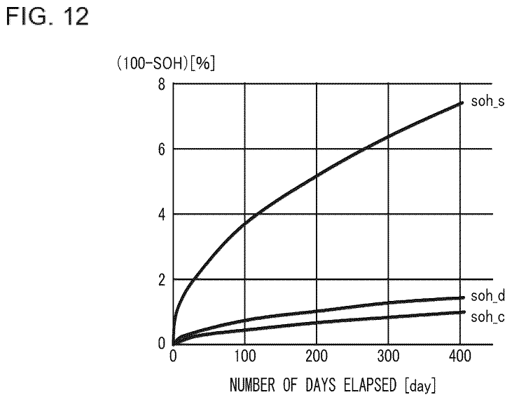

FIG. 12 is a diagram that shows an example of the analysis results of a breakdown of a storage degradation amount soh_s, a charging degradation amount soh_c, and a discharging degradation amount soh_d.

### DETAILED DESCRIPTION OF THE INVENTION

The invention will now be described by reference to the preferred embodiments. This does not intend to limit the scope of the present invention, but to exemplify the invention.

FIG. 1 is a diagram showing a schematic configuration of an electrically driven vehicle 3 according to an embodiment. In the present embodiment, a plain EV without an internal combustion engine is assumed as the electrically driven vehicle 3. The electrically driven vehicle 3 shown in FIG. 1 is a rear-wheel drive (2WD) EV equipped with a pair of front wheels 31f, a pair of rear wheels 31r, and a motor 34 as a power source. The pair of front wheels 31f are connected by a front wheel axle 32f, and the pair of rear wheels 31r are connected by a rear wheel axle 32r. A transmission 33 transmits the rotation of the motor 34 to the rear wheel axle 32r at a predetermined conversion ratio. The electrically driven vehicle 3 may be a front-wheel drive (2WD) or 4WD electrically driven vehicle.

The power supply system 40 has a battery pack 41 and a management unit 42, and the battery pack 41 includes a plurality of cells. For the cells, lithium-ion battery cells, nickel hydrogen battery cells, etc., can be used. Hereinafter, an example is assumed in the present specification where lithium-ion battery cells, with nominal voltage of 3.6-3.7 V, are used. The management unit 42 monitors and measures the voltage, current, temperature, and SOC of the plurality of cells included in the battery pack 41, and transmits the data to a vehicle control unit 30 via an in-vehicle network as usage data of the plurality of cells. For example, a controller area network (CAN) or a local interconnect network (LIN) can be used as the in-vehicle network. The management unit 42 also transmits battery information. e.g., model number, to the vehicle control unit 30 to specify the type of the plurality of cells included in the battery pack 41. The battery information only needs to be transmitted once at the beginning.

In general, three-phase AC motors are used for motors 34 for driving in EVs. An inverter 35 converts DC power supplied from the battery pack 41 into AC power and supplies the AC power to the motor 34 during power running. During regeneration, the inverter converts the AC power supplied from the motor 34 to DC power and supplies the DC power to the battery pack 41. The motor 34 rotates according to the AC power supplied from the inverter 35 during power running. During regeneration, the motor converts rotational energy caused due to deceleration to AC power and supplies the Ac power to the inverter 35.

The vehicle control unit 30 is a vehicle electronic control unit (ECU) that controls the entire electrically driven vehicle 3 and may consist of, for example, an integrated vehicle control module (VCM).

A vehicle speed sensor 36 generates a pulse signal proportional to the rotation speed of the front wheel axle 32f or the rear wheel axle 32r and transmits the generated pulse signal to the vehicle control unit 30. The vehicle control unit 30 detects the speed of the electrically driven vehicle 3 based on the pulse signal received from the vehicle speed sensor 36.

The wireless communication unit 37 has a modem for wireless connection to a network 5 (see FIG. 2) via an antenna 37a so as to perform a wireless signal process. For example, cellular phone networks (cellular networks), wireless LAN, vehicle-to-infrastructure (V2I), vehicle-to-vehicle (V2V), electronic toll collection systems (ETC systems), and dedicated short range communications (DSRC) can be used.

A display unit 38 is a display capable of displaying text and video images, and an LCD liquid crystal display, organic EL display, mini LED display, or the like can be used. The display unit 38 may be a display converted from a car navigation system, display audio equipment, drive recorder, etc., or may be a display installed in a meter panel. The display used for the display unit 38 may have a touch panel function. In the present embodiment, comments and other information regarding how to use the battery pack 41 can be displayed on the display unit 38.

While the electrically driven vehicle 3 is traveling, the vehicle control unit 30 can transmit traveling data in real time from the wireless communication unit 37 to a data server 4 (see FIG. 2) via the network 5. The traveling data includes at least the vehicle speed of the electrically driven vehicle 3, the voltage, current, temperature, and SOC of the plurality of cells in the battery pack 41. The vehicle control unit 30 takes a sample of these pieces of data periodically, e.g., at 10-second intervals, and transmits the sample to the data server 4 each time. During the initial transmission, the vehicle control unit 30 also transmits battery information, e.g., model number, to the data server 4.

The vehicle control unit 30 may store the traveling data of the electrically driven vehicle 3 in an internal memory and transmit the traveling data stored in the memory in a batch at a predetermined time. For example, the vehicle control unit 30 may transmit the traveling data stored in the memory in a batch to an operation management terminal device 2 (see FIG. 2) installed at a delivery operator's base after the end of the day's business. The operation control terminal device 2 transmits the traveling data of the plurality of electrically driven vehicles 3 to the data server 4 each time at a predetermined time.

During charging from a charger with a network communication function, the vehicle control unit 30 may also transmit the traveling data stored in the memory to the charger via a charging cable. The charger transmits the received traveling data to the data server 4. This example is effective for electrically driven vehicles 3 that are not equipped with wireless communication functions.

FIG. 2 is a diagram for explaining a degradation state estimation system 1 according to the embodiment. The degradation state estimation system 1 is a system used by at least one delivery operator. The degradation state estimation system 1 may, for example, be constructed on an in-house server installed in an in-house facility or data center of a business that provides a degradation analysis service for the battery pack 41 mounted on the electrically driven vehicle 3. Further, the degradation state estimation system 1 may be constructed on a cloud server used based on a cloud service. Also, the degradation state estimation system 1 may be constructed on a plurality of servers distributed and installed at a plurality of bases, which are data centers and in-house facilities. The plurality of servers may be any of a combination of a plurality of in-house servers, a combination of a plurality of cloud servers, or a combination of an in-house server and a cloud server. In the example shown in FIG. 2, the degradation state estimation system 1 is constructed on a calculation server 1a and a degradation characteristic holding server 1b.

The delivery operator has a plurality of electrically driven vehicles 3 and a delivery base for parking the electrically driven vehicles 3. An operation management terminal device 2 is installed at the delivery base. The operation management terminal device 2 consists of a PC, for example. The operation management terminal device 2 is used to manage the plurality of electrically driven vehicles 3 belonging to the delivery base. The operation manager of the delivery operator can use the operation management terminal device 2 so as to create operation plans for the electrically driven vehicles 3.

The operation management terminal device 2 can access the degradation state estimation system 1 via the network 5. The operation management terminal device 2 can obtain from the degradation state estimation system 1 at least one of the SOH of the battery pack 41 installed in each electrically driven vehicle 3 and a comment regarding how to use each battery pack 41.

The data server 4 acquires and accumulates the traveling data from the operation management terminal device 2 or the electrically driven vehicles 3. The data server 4 may be an in-house server installed at an in-house facility of the delivery operator or the degradation analysis service provider or at a data center, or may be a cloud server used by the delivery operator or the degradation analysis service provider. Alternatively, each delivery operator and the degradation analysis service provider may each have a data server 4.

The network 5 is a general term for communication channels such as the Internet, a leased line, a virtual private network (VPN), etc., regardless of their communication media or protocols. As the communication media, for example, cellular phone networks (cellular networks), wireless LANs, wired LANs, optical fiber networks, ADSL networks, CATV networks, etc., can be used. For example, transmission control protocol (TCP)/internet protocol (IP), user datagram protocol (UDP)/IP, Ethernet (registered trademark), etc., can be used as the communication protocols.

The operation manager of the delivery operator can communicate with drivers in the electrically driven vehicles 3 via the network 5, e.g., IP radio, commercial radio, specific low power radio, etc. The operation manager can transmit to the drivers comments and other information regarding how to use the battery pack 41 acquired from the degradation state estimation system 1.

When an electrically driven vehicle 3 is parked at a delivery base, the vehicle control unit 30 and the operation management terminal device 2 can exchange data via the network 5, e.g., wireless LAN, CAN cable, or the like. The vehicle control unit 30 and the operation management terminal device 2 may be configured to be able to exchange data via the network 5 even when the electrically driven vehicle 3 is traveling.

FIG. 3 is a diagram showing a configuration example of the degradation state estimation system 1 according to the embodiment. The degradation state estimation system 1 includes a processing unit 11, a memory unit 12, and a communication unit 13. The communication unit 13 is a communication interface, e.g. network interface card (NIC), for connecting to the network 5 by wire or wirelessly.

The processing unit 11 includes a data acquisition unit 111, a degradation characteristic search unit 112, a degradation state analysis unit 113, an SOH estimation unit 114, a degradation cause specifying unit 115, a comment generation unit 116, and a notification unit 117. The function of the processing unit 11 can be realized by cooperation of hardware resources and software resources, or only by hardware resources. As the hardware resources, CPU, ROM, RAM, graphics processing unit (GPU), application specific integrated circuit (ASIC), field programmable gate array (FPGA), and other LSIs can be used. Programs such as operating systems and applications can be used as the software resources.

The memory unit 12 includes a non-volatile recording medium such as HDD, SSD, etc., and stores various types of data. The memory unit 12 includes a battery degradation characteristic holding unit 121. The battery degradation characteristic holding unit 121 holds a storage degradation characteristic, a storage degradation speed coefficient ps, a charging degradation characteristic, a charging degradation speed coefficient pc, a discharging degradation characteristic, a discharging degradation speed coefficient pd for each type of secondary batteries.

The battery degradation characteristic holding unit 121 holds at least one of the following information as battery information for specifying the type of secondary battery: model number; model type; cell shape; positive electrode material; composition ratio of positive electrode material; negative electrode material; composition ratio of negative electrode material; energy weight density; and energy volume density. The data in the battery degradation characteristic holding unit 121 is updated each time a new type of secondary battery is registered. The data in the battery degradation characteristic holding unit 121 is also updated when the characteristic information of an already registered secondary battery is updated.

The storage degradation of a secondary battery is degradation that progresses over time depending on the temperature of the secondary battery at each point of time and the SOC at each point of time. The storage degradation progresses regardless of whether or not the secondary battery is being charged or discharged. The storage degradation mainly occurs due to the formation of a coating film (solid electrolyte interphase (SEI) film) on the negative electrode. The storage degradation depends on the SOC and the temperature at each point of time. Generally, the higher the SOC at each point of time and the higher the temperature at each point of time, the higher the degradation speed.

The charging and discharging degradation of a secondary battery is degradation that progresses as the number of times of charging and discharging increases. Charging and discharging degradation occurs mainly due to cracking, peeling, or the like caused due to expansion or contraction of active materials. The charging and discharging degradation depends on the SOC range that is used, the temperature, and a current rate. In general, the wider the SOC range that is used, the higher the temperature, and the higher the current rate, the higher the charging and discharging degradation rate.

The storage degradation characteristic, the charging degradation characteristic, and the discharging degradation characteristic are derived in advance for each secondary battery type through experiments and simulations performed by battery manufacturers.

FIG. 4 is a diagram showing an example of a storage degradation characteristic map. The horizontal axis shows SOC [%], and the vertical axis shows a storage degradation coefficient Ks. In general, storage degradation progresses approximately linearly with respect to a value obtained by raising elapsed time (h) to the power of 0.5 (square root). Depending on the type of secondary battery, storage degradation may also progress approximately linearly with respect to a value obtained by raising the elapsed time (h) to the power of 0.4, a value obtained by raising the elapsed time (h) to the power of 0.6, or the like. In the present specification, the coefficient by which the elapsed time (h) is multiplied is referred to as the storage degradation speed coefficient ps.

For the purpose of simplification, FIG. 4 only depicts the storage degradation characteristics for two temperatures temp, which are 25 degrees Celsius and 45 degrees Celsius. In reality, however, storage degradation characteristics are generated for a large number of temperatures temp. The storage degradation characteristics may be defined not as a map but as a storage degradation characteristic model (function) with SOC and a temperature temp as explanatory variables and the storage degradation coefficient Ks as an objective variable.

FIGS. 5A and 5B are diagrams each showing an example of a charging/discharging degradation characteristic map. FIG. 5A shows an example of a charging degradation characteristic map and FIG. 5B shows an example of a discharging degradation characteristic map. The horizontal axis indicates the usage range of SOC [%]. In FIGS. 5A to 5B, each SOC value indicates the lower limit of a 10 percent usage range. For example, 10 percent SOC indicates that the SOC is charged and discharged in the range of 10 to 20 percent, and 11 percent SOC indicates that the SOC is charged and discharged in the range of 11 to 21 percent. The vertical axis shows the charging/discharging degradation coefficients Kc and Kd.

In general, charging and discharging degradation progresses approximately linearly with respect to a value obtained by raising the total charging amount or total discharging amount (Ah) to the power of 0.5 (square root). Depending on the type of secondary battery, charging and discharging degradation may also progress approximately linearly with respect to a value obtained by raising the total charging amount or total discharging amount (Ah) to the power of 0.4, a value obtained by raising the total charging amount or total discharging amount (Ah) to the power of 0.6, or the like. In the present specification, the coefficient by which the total charge amount (Ah) is multiplied is referred to as the charging degradation speed coefficient pc, and the coefficient by which the total discharging amount (Ah) is multiplied is referred to as the discharging degradation speed coefficient pd.

For the purpose of simplification, FIG. 5A to 5B only depict the charging/discharging degradation characteristics for two current rates rate, 0.1 C and 0.8 C. However, in reality, charging/discharging degradation characteristics are generated for a large number of current rates rate. As shown in FIG. 5A, it can be seen that the charging/discharging degradation speed increases in low and high SOC usage range regions at the time of charging. As shown in FIG. 5B, it can be seen that the charging/discharging degradation speed increases in a low SOC usage range region at the time of discharging.

Further, the charging/discharging degradation characteristic is also affected by temperature temp, although the temperature does not contribute as much as the current rate rate. Therefore, in order to increase the estimation accuracy of the charging/discharging degradation speed, it is preferable to prepare charging/discharging degradation characteristics that define the relationship between the SOC usage range and the charging/discharging degradation coefficient for each two-dimensional combination of a plurality of current rates rate and a plurality of temperatures temp. On the other hand, when generating a simplified charging/discharging degradation characteristic map, the temperature is considered to be room temperature, and it is only necessary to prepare a charging/discharging degradation characteristic for each of the plurality of current rates rate.

The charging/discharging degradation characteristics may be defined not as a map but as a charging/discharging degradation characteristic model (function) with a SOC usage range, a current rate rate, and a temperature temp as explanatory variables and the charging/discharging degradation coefficients Kc and Kd as objective variables. The temperature temp may be a constant.

The description now returns to FIG. 3. The data acquisition unit 111 acquires usage data and battery information of each cell of the battery pack 41 included in the traveling data of a target electrically driven vehicle 3 from the data server 4. The degradation characteristic search unit 112 searches a degradation characteristic database in the battery degradation characteristic holding unit 121 based on the acquired battery information, and specifies storage characteristic information of the cell.

When a secondary battery of the same type as the type specified by the acquired battery information is found, the degradation characteristic search unit 112 acquires the degradation characteristic information of the secondary battery. If a secondary battery of the same type is not found, the degradation characteristic search unit 112 searches the degradation characteristic database for degradation characteristic information of a secondary battery of a type most similar to the specified type. A cylindrical cell is used as a search range in the degradation characteristic database if the shape of the cell to be searched is cylindrical, and a rectangular cell is used as the search range if the shape of the cell to be searched is rectangular.

FIG. 6 is a flowchart for explaining an example of a degradation characteristic search method. In the example shown in FIG. 6, it is assumed that a ternary material (NCM) is used as the positive electrode material of the cell to be searched, and a mixed material of graphite and silicon is used as the negative electrode material. The composition ratio of the positive electrode material of the target cell is expressed as a:b:c, for example, NCM532, and the composition ratio of the positive electrode material of a reference cell in the database is expressed as d:e:f. Further, the composition ratio of the negative electrode material of the target cell is expressed as g:h, for example, graphite 97:silicon 3, and the composition ratio of the negative electrode material of the reference cell in the database is expressed as i:j. Further, the energy weight density [wh/kg] of the target cell is denoted as k, the energy volume density [wh/L] is denoted as l, the energy weight density [wh/kg] of the reference cell is denoted as m, and the energy volume density [wh/L] is denoted as n.

The degradation characteristic search unit 112 solves the following (Expression 1) so as to calculate a positive electrode material similarity degree SP between the target cell and the reference cell (S50), solves the following (Expression 2) so as to calculate a negative electrode material similarity degree SN (S51), and solves the following (Expression 3) so as to calculate an energy density similarity degree SE (S52). The higher the similarity degree, the higher the score in all the expressions.

$$SP = 100 - [ abs ( a - d ) + abs ( b - e ) + abs ( c - f ) ] \qquad ( Expression 1 )$$

$$SN = 100 - [ abs ( g - i ) + abs ( h - j ) ] \qquad ( Expression 2 )$$

$$SE = 100 - [ abs ( k - m ) / ( k + m ) + abs ( 1 - n ) / ( 1 + n ) ] \qquad ( Expression 3 )$$

The degradation characteristic search unit 112 solves the following (Expression 4) so as to calculate a total similarity degree S between the target cell and the reference cell (S53). w1, w2, and w3 (w1+w2+w3=1) represent weighting factors. w1, w2, and w3 are determined based on the evaluation results obtained based on experiments and simulations, as well as the knowledge of the designer.

$$S = w 1 * SP + w 2 * SN + w 3 * SE \qquad ( Expression 4 )$$

The degradation characteristic search unit 112 calculates respective total similarity degrees S between the target cell and a plurality of reference cells, and specifies a reference cell having the highest total similarity degree S (S54). The degradation characteristic search unit 112 acquires degradation characteristic information of the specified cell (S55).

The description now returns to FIG. 3. The degradation state analysis unit 113 generates usage data (voltage, current, temperature, and SOC) of a synthesis circuit of the plurality of cells constituting the battery pack 41 based on the usage data (voltage, current, temperature, and SOC) of each of the cells constituting the target battery pack 41. The degradation state analysis unit 113 may analyze the degradation state of the battery pack 41 based on the usage data of the synthesis circuit, or may analyze the degradation state of a single cell by converting the usage data of the synthesis circuit into the usage data of the single cell. For example, the degradation state analysis unit 113 may average the voltage, current, temperature, and SOC of a plurality of cells constituting the battery pack 41 respectively, and obtain a voltage, current, temperature, and SOC of a single cell.

The degradation state analysis unit 113 estimates a storage degradation amount, a charging degradation amount, and a discharging degradation amount for the cell on the basis of the degradation characteristic information specified by the degradation characteristic search unit 112 and the usage data of the cell. More specifically, the degradation state analysis unit 113 estimates the storage degradation amount of the cell based on the storage degradation characteristic specified by the degradation characteristic search unit 112 and on the SOC, temperature, and elapsed time obtained based on the usage data of the cell. Further, the degradation state analysis unit 113 estimates the charging degradation amount of the cell based on the charging degradation characteristic specified by the degradation characteristic search unit 112 and on the SOC, charging rate, temperature, and charging amount obtained based on the usage data of the cell. Further, the degradation state analysis unit 113 estimates the discharging degradation amount of the cell based on the discharging degradation characteristic specified by the degradation characteristic search unit 112 and on the SOC, discharging rate, temperature, and discharging amount obtained based on the usage data of the cell.

The SOH estimation unit 114 adds up the storage degradation amount, the charging degradation amount, and the discharging degradation amount of the cell estimated by the degradation state analysis unit 113 so as to estimate the SOH of the cell. When estimating the SOH of the cell, the SOH estimation unit 114 may correct the storage degradation amount of the cell using the SOH obtained at the time of storage of the cell. Further, the SOH estimation unit 114 may correct the charging degradation amount of the cell using the depth of discharge (DOD) for the amount that has changed due to the current charging cycle of the cell. Further, the SOH estimation unit 114 may correct the discharging degradation amount of the cell using DOD for the amount that has changed due to the current discharging cycle of the cell.

FIG. 7 is a flowchart for explaining a process of estimating SOH according to the embodiment. FIG. 8 is a flowchart that shows a subroutine for explaining a process of estimating a storage degradation increase amount Δsoh_s. FIG. 9 is a flowchart that shows a subroutine for explaining a process of estimating a charging degradation increase amount Δsoh_c. FIG. 10 is a flowchart that shows a subroutine for explaining a process of estimating a discharging degradation increase amount Δsoh_d.

In FIG. 7, when the condition for updating the storage degradation amount soh_s is satisfied (Y of S10), the degradation state analysis unit 113 executes a process of estimating the storage degradation increase amount Δsoh_s (S11). The condition for updating the storage degradation amount soh_s may be the passage of a predetermined time, e.g., 24 hours, or a predetermined change in the temperature of the cell.

In FIG. 8, the degradation state analysis unit 113 acquires the latest storage degradation amount soh_s [%], SOC [%], temperature temp [° C.], and elapsed time Δtime [h] of the cell as input parameters (S12). The degradation state analysis unit 113 acquires the storage degradation characteristic and the storage degradation speed coefficient ps included in the storage degradation information specified by the degradation characteristic search unit 112. The degradation state analysis unit 113 acquires the storage degradation coefficient Ks by inputting the acquired SOC and temperature temp in the acquired storage degradation characteristic (S13).

The degradation state analysis unit 113 inputs the latest storage degradation amount soh_s, the storage degradation coefficient Ks, and the storage degradation speed coefficient ps that have been acquired to a predetermined total elapsed time derivation function Fs1, and acquires a pseudo total elapsed time totaltime (S14). The degradation state analysis unit 113 inputs the storage degradation coefficient Ks, the pseudo total elapsed time totaltime, and the elapsed time Δtime that have been acquired to a predetermined storage degradation amount derivation function Fs2, and estimates the storage degradation increase amount Δsoh_s (S15).

The description now returns to FIG. 7. The degradation state analysis unit 113 inputs the acquired storage degradation increase amount Δsoh_s and the current SOH to a predetermined storage degradation amount correction function Fs3, and estimates a corrected storage degradation increase amount Δsoh_s′ (S16). The degradation state analysis unit 113 adds the corrected storage degradation increase amount Δsoh_s′ to the current storage degradation amount soh_s so as to update the storage degradation amount soh_s (S17). The SOH estimation unit 114 subtracts from 100 the value obtained by adding up the updated storage degradation amount soh_s, the current charging degradation amount soh_c, and the current discharging degradation amount soh_d so as to calculate the latest SOH (S18). The step goes back to S10.

When the condition for updating the charging degradation amount soh_c is satisfied (Y at S20), the degradation state analysis unit 113 executes a process of estimating the charging degradation increase amount Δsoh_c (S21). The condition for updating the charging degradation amount soh_c may be the passage of a predetermined time, e.g., 24 hours, or a predetermined change, e.g., a change of five percent, in the SOC of the cell.

In FIG. 9, the degradation state analysis unit 113 acquires the latest charging degradation amount soh_c [%], SOC [%], charging rate rate [C], temperature temp [° C.], and charging amount Δcap_c [Ah] of the cell as input parameters (S22). The degradation state analysis unit 113 acquires the charging degradation characteristic and the charging degradation speed coefficient pc included in the charging degradation information specified by the degradation characteristic search unit 112. The degradation state analysis unit 113 acquires a charging degradation coefficient Kc by inputting the acquired SOC, charging rate rate, and temperature temp to the acquired charging degradation characteristic (S23).

The degradation state analysis unit 113 inputs the latest charging degradation amount soh_c, charging degradation coefficient Kc, and charging degradation speed coefficient pc that have been acquired to a predetermined total charging amount derivation function Fc1, and acquires a pseudo total charging amount chgcap (S24). The degradation state analysis unit 113 inputs the acquired charging degradation coefficient Kc, the pseudo total charging amount chgcap, and the charging amount Δcap_c to a predetermined charging degradation amount derivation function Fc2, and estimates the charging degradation increase amount Δsoh_c (S25).

The description now returns to FIG. 7. The degradation state analysis unit 113 inputs the acquired charging degradation increase amount Δsoh_c and the DOD of an amount changed due to the current charging cycle to a predetermined charging degradation amount correction function Fc3, and estimates a corrected charging degradation increase amount Δsoh_c′ (S26). The degradation state analysis unit 113 adds the corrected charging degradation increase amount Δsoh_c′ to the current charging degradation amount soh_c so as to update the charging degradation amount soh_c (S27). The SOH estimation unit 114 subtracts from 100 the value obtained by adding up the updated charging degradation amount soh_c, the current storage degradation amount soh_s, and the current discharging degradation amount soh_d so as to calculate the latest SOH (S28). The step goes back to S10.

When the condition for updating the discharging degradation amount soh_d is satisfied (Y at S30), the degradation state analysis unit 113 executes a process of estimating the discharging degradation increase amount Δsoh_d (S31). The condition for updating the discharging degradation amount soh_d may be the passage of a predetermined time, e.g., 24 hours, or a predetermined change, e.g., a change of five percent, in the SOC of the cell.

In FIG. 10, the degradation state analysis unit 113 acquires the latest discharging degradation amount soh_d [%], SOC [%], discharging rate rate [C], temperature temp [° C.], and discharging amount Δcap_d [Ah] of the cell as input parameters (S32). The degradation state analysis unit 113 acquires the discharging degradation characteristic and the discharging degradation speed coefficient pd included in the discharging degradation information specified by the degradation characteristic search unit 112. The degradation state analysis unit 113 acquires a discharging degradation coefficient Kd by inputting the acquired SOC, discharging rate rate, and temperature temp to the acquired discharging degradation characteristic (S33).

The degradation state analysis unit 113 inputs the latest discharging degradation amount soh_d, discharging degradation coefficient Kd, and discharging degradation speed coefficient pd that have been acquired to a predetermined total discharging amount derivation function Fd1, and acquires a pseudo total discharging amount discap (S34). The degradation state analysis unit 113 inputs the acquired discharging degradation coefficient Kd, the pseudo total charging amount discap, and the discharging amount Δcap_d to a predetermined discharging degradation amount derivation function Fd2, and estimates the discharging degradation increase amount Δsoh_d (S35).

The description now returns to FIG. 7. The degradation state analysis unit 113 inputs the acquired discharging degradation increase amount Δsoh_d and the DOD of an amount changed due to the current discharging cycle to a predetermined discharging degradation amount correction function Fd3, and estimates a corrected discharging degradation increase amount Δsoh_d′ (S36). The degradation state analysis unit 113 adds the corrected discharging degradation increase amount Δsoh_d′ to the current discharging degradation amount soh_d so as to update the discharging degradation amount soh_d (S37). The SOH estimation unit 114 subtracts from 100 the value obtained by adding up the updated discharging degradation amount soh_d, the current storage degradation amount soh_s, and the current charging degradation amount soh_c so as to calculate the latest SOH (S38). Until a degradation estimation process is stopped (Y at S40), the above process is continuously executed (N at S40).

FIG. 11 is a diagram that compares the transition of the SOH of a cell simulated by a degradation state estimation method according to the embodiment and the transition of the SOH of a cell based on actual measurement results. The example shown in FIG. 11 is based on charging/discharging data corresponding to a traveling pattern defined in a JC08 mode. The latter SOH is a value measured by charging and discharging an actual cell using a charging/discharging test device. It has been confirmed that the transition of SOH calculated by the degradation state estimation method according to the embodiment is almost the same as the transition of SOH of the actual cell.

The description now returns to FIG. 3. The degradation cause specifying unit 115 specifies a main cause of cell degradation based on a breakdown of the storage degradation soh_s, the charging degradation amount soh_c, and the discharging degradation amount soh_d of the cell estimated by the degradation state analysis unit 113. For example, the degradation cause specifying unit 115 specifies the largest of the storage degradation amount soh_s, the charging degradation amount soh_c, and the discharging degradation amount soh_d as the main cause. When the difference between the largest degradation amount and the second largest degradation amount is less than a predetermined value and the difference between the second largest degradation amount and the third largest degradation amount is greater than the predetermined value, the degradation cause specifying unit 115 may specify two degradation causes as the main causes of cell degradation. For example, when the ratio of the storage degradation amount soh_s, the charging degradation amount soh_c, and the discharging degradation amount soh_d falls within a predetermined range, the degradation cause specifying unit 115 does not need to specify the main causes of cell degradation.

FIG. 12 is a diagram that shows an example of the analysis results of a breakdown of the storage degradation amount soh_s, the charging degradation amount soh_c, and the discharging degradation amount soh_d. In the example shown in FIG. 12, it can be specified that the storage degradation amount soh_s is the largest and is the main cause of degradation.

The description now returns to FIG. 3. The comment generation unit 116 generates a comment on how to use the battery pack 41 including the cell to be presented to the user based on the main cause of the degradation of the cell specified by the degradation cause specifying unit 115. For example, if storage degradation is the main cause, the comment generation unit 116 generates a comment such as “Please store at a lower temperature.” or “Please store at a lower battery level.” If charging degradation is the main cause, the comment generation unit 116 generates a comment such as “Please increase the charging time.” or “Please lower the charging current.” If discharging degradation is the main cause, the comment generation unit 116 generates a comment such as “Please refrain from sudden acceleration.” If no primary cause is specified, the comment generation unit 116 generates a comment such as “Please continue with the current usage.” The comment may be written in advance in a program or may be extracted from a comment database.

Via the network 5, the notification unit 117 notifies the operation management terminal device 2 of the SOH of the battery pack 41 estimated by the SOH estimation unit 114. Further, via the network 5, the notification unit 117 notifies the operation management terminal device 2 of a comment on how to use the battery pack 41 generated by the comment generation unit 116. The operation manager transmits the details of the acquired comment to the driver of an electrically driven vehicle 3 equipped with the battery pack 41. The comment acquired by the operation management terminal device 2 may be transmitted to the vehicle control unit 30, and the vehicle control unit 30 may receive the comment and display the comment on the display unit 38. The comment may be transmitted directly from the degradation state estimation system 1 to the vehicle control unit 30.

As explained above, according to the present embodiment, sequential integration of a storage degradation amount soh_s, a charging degradation amount soh_c, and a discharging degradation amount soh_d allows for the estimation of the degradation state of a secondary battery with high accuracy. The method of estimating the degradation state based on the current full charge capacity based on capacity measurement may not reflect the actual degradation state inside the battery. Further, since the calculation is not made by an integration method, there is a possibility that a large error may occur in the calculated SOH due to the influence of measurement errors and the like. In addition, it is not possible to analyze which method of use, storage, charging, or discharging, is the main cause of the degradation.

On the other hand, in the degradation state estimation method according to the present embodiment, it is possible to quantitatively calculate which method of use, storage, charging, or discharging, is the main cause of the degradation. Based on the results of this analysis, it is possible to present the user with advice on how to improve the use of the battery pack 41 that leads to suppression of degradation of the battery pack 41.

The user may be presented with a graph showing the transition of a breakdown of the storage degradation amount soh_s, the charge degradation amount soh_c, and the discharge degradation amount soh_d. In that case, it is possible to visualize changes in the transition of the degradation state through how to use the battery pack 41, and the user's motivation can be enhanced.

Further, in the degradation state estimation method according to the present embodiment, since SOH is calculated by sequentially integrating the amount of increase in the storage degradation amount soh_s, the charge degradation amount soh_c, and the discharge degradation amount soh_d, no large error occurs in SOH. Further, there is no need to construct a complex battery chemical reaction model, and an increase in computational cost can thus be suppressed.

Described above is an explanation based on the embodiments of the present disclosure. The embodiments are intended to be illustrative only, and it will be obvious to those skilled in the art that various modifications to constituting elements and processes could be developed and that such modifications are also within the scope of the present disclosure.

The degradation state estimation system 1 described above may be implemented in the management unit 42 of the power supply system 40 in the electrically driven vehicle 3. In this case, although a large capacity memory is required, data transmission can be eliminated.

Four-wheeled electric vehicles are assumed as electrically driven vehicles 3 in the above embodiment. In this regard, electric motorcycles (electric scooters), electric bicycles, and electric kick scooters may also be used. Further, the electrically driven vehicles include not only full-standard electric vehicles but also low-speed electric vehicles such as golf carts and land cars. Further, targets on which a battery pack 41 is to be mounted are not limited to electrically driven vehicles 3. The targets on which a battery pack 41 is to be mounted include electric ships, railway vehicles, electric mobile objects such as multicopters (drones), stationary power storage systems, and consumer electronic devices (smartphones, laptop PCs, etc.).

The embodiment may be specified by the following items.

[Item 1] A degradation state estimation system (1) including:
a data acquisition unit (111) that acquires usage data of a secondary battery (41) and battery information for specifying the type of the secondary battery (41);
a degradation characteristic search unit (112) that searches a degradation characteristic database (121) on the basis of the battery information and specifies degradation characteristic information that includes a storage degradation characteristic, a charging degradation characteristic, and a discharging degradation characteristic of the secondary battery (41); and
a degradation state analysis unit (113) that estimates a storage degradation amount, a charging degradation amount, and a discharging degradation amount of the secondary battery (41) on the basis of the specified degradation characteristic information and the usage data of the secondary battery (41),
wherein the degradation state analysis unit (113) performs:
estimating a storage degradation amount of the secondary battery (41) on the basis of the specified storage degradation characteristic and state of charge (SOC), temperature, and elapsed time obtained based on the usage data of the secondary battery (41);
estimating a charging degradation amount of the secondary battery (41) on the basis of SOC, a charging rate, temperature, and a charging amount obtained based on the specified charging degradation characteristic and the usage data of the secondary battery (41); and
estimating a discharging degradation amount of the secondary battery (41) on the basis of SOC, a discharging rate, temperature, and a discharging amount obtained based on the specified discharging degradation characteristic and the usage data of the secondary battery (41).

This allows for highly accurate estimation of the degradation state of the secondary battery (41) including degradation causes.

[Item 2] The degradation state estimation system (1) further including:
an SOH estimation unit (114) that adds up the storage degradation amount, the charging degradation amount, and the discharging degradation amount of the secondary battery (41) estimated by the degradation state analysis unit (113) so as to estimate the state of health (SOH) of the secondary battery (41).

This allows for highly accurate estimation of the SOH of the secondary battery (41).

[Item 3] The degradation state estimation system (1) according to Item 2,
wherein the SOH estimation unit (114) performs:
correcting the estimated storage degradation amount of the secondary battery (41) using SOH obtained at the time of storage of the secondary battery (41);
correcting the estimated charging degradation amount of the secondary battery (41) using the depth of discharge (DOD) for an amount that has changed due to the current charging cycle of the secondary battery (41);
correcting the estimated discharging degradation amount of the secondary battery (41) using the DOD for an amount that has changed due to the current discharging cycle of the secondary battery (41); and
adding up the estimated storage degradation amount of the secondary battery (41), the estimated charging degradation amount of the secondary battery (41), and the estimated discharging degradation amount of the secondary battery (41).

This allows for highly accurate estimation of each of the storage degradation amount, the charging degradation amount, and the discharging degradation amount of the secondary battery (41).

[Item 4] The degradation state estimation system (1) according to any one of Items 1 through 3,
wherein the degradation state analysis unit (113) calculates the amount of increase in the storage degradation amount of the secondary battery (41) each time a predetermined time elapses or each time the temperature of the secondary battery (41) changes by a predetermined temperature, adds the amount of increase to the previously calculated storage deterioration amount of the secondary battery (41), and updates the storage deterioration amount of the secondary battery (41).

This allows for highly accurate estimation of the storage degradation amount of the secondary battery (41) by sequentially integrating the amount of increase in the storage degradation amount of the secondary battery (41).

[Item 5] The degradation state estimation system (1) according to any one of Items 1 through 4,
wherein the degradation state analysis unit (113) calculates the amount of increase in the charging degradation amount or discharging degradation amount of the secondary battery (41) each time a predetermined time elapses or each time the SOC of the secondary battery (41) changes by a predetermined value, adds the amount of increase to the previously calculated charging degradation amount or discharging degradation amount of the secondary battery (41), and updates the charging degradation amount or discharging degradation amount of the secondary battery (41).

This allows for highly accurate estimation of the charging degradation amount or discharging degradation amount of the secondary battery (41) by sequentially integrating the amount of increase in the charging degradation amount or discharging degradation amount of the secondary battery (41).

[Item 6] The degradation state estimation system (1) according to any one of Item 1 through Item 5, further including:
a degradation cause specifying unit (115) that specifies a main cause of the degradation of the secondary battery (41) based on a breakdown of the storage degradation amount, the charging degradation amount, and the discharging degradation amount of the secondary battery (41) estimated by the degradation state analysis unit (113); and
a comment generation unit (116) that generates a comment on how to use the secondary battery (41) to be presented to the user based on the specified main cause of the degradation of the secondary battery (41).

This allows for the presentation of useful information for suppressing the degradation of the secondary battery (41).

[Item 7] A degradation state estimation method including:
acquiring usage data of a secondary battery (41) and battery information for specifying the type of the secondary battery (41);
searching a degradation characteristic database (121) on the basis of the battery information and specifying degradation characteristic information that includes a storage degradation characteristic, a charging degradation characteristic, and a discharging degradation characteristic of the secondary battery (41); and
estimating a storage degradation amount, a charging degradation amount, and a discharging degradation amount of the secondary battery (41) on the basis of the specified degradation characteristic information and the usage data of the secondary battery (41),
wherein the estimating includes:
estimating a storage degradation amount of the secondary battery (41) on the basis of the specified storage degradation characteristic and SOC, temperature, and elapsed time obtained based on the usage data of the secondary battery (41);
estimating a charging degradation amount of the secondary battery (41) on the basis of SOC, a charging rate, temperature, and a charging amount obtained based on the specified charging degradation characteristic and the usage data of the secondary battery (41); and
estimating a discharging degradation amount of the secondary battery (41) on the basis of SOC, a discharging rate, temperature, and a discharging amount obtained based on the specified discharging degradation characteristic and the usage data of the secondary battery (41).

This allows for highly accurate estimation of the degradation state of the secondary battery (41) including degradation causes.

[Item 8] A degradation state estimation program including computer-implemented modules including:
a module that acquires usage data of a secondary battery (41) and battery information for specifying the type of the secondary battery (41);
a module that searches a degradation characteristic database (121) on the basis of the battery information and specifies degradation characteristic information that includes a storage degradation characteristic, a charging degradation characteristic, and a discharging degradation characteristic of the secondary battery (41);
a module that estimates a storage degradation amount, a charging degradation amount, and a discharging degradation amount of the secondary battery (41) on the basis of the specified degradation characteristic information and the usage data of the secondary battery (41),
wherein the module that estimates the storage degradation amount includes:
estimating a storage degradation amount of the secondary battery (41) on the basis of the specified storage degradation characteristic and SOC, temperature, and elapsed time obtained based on the usage data of the secondary battery (41);
estimating a charging degradation amount of the secondary battery (41) on the basis of SOC, a charging rate, temperature, and a charging amount obtained based on the specified charging degradation characteristic and the usage data of the secondary battery (41); and
estimating a discharging degradation amount of the secondary battery (41) on the basis of SOC, a discharging rate, temperature, and a discharging amount obtained based on the specified discharging degradation characteristic and the usage data of the secondary battery (41).

This allows for highly accurate estimation of the degradation state of the secondary battery (41) including degradation causes.

1. A degradation state estimation system comprising:
a data acquisition unit that acquires usage data of a secondary battery and battery information for specifying the type of the secondary battery;
a degradation characteristic search unit that searches a degradation characteristic database on the basis of the battery information and specifies degradation characteristic information that includes a storage degradation characteristic, a charging degradation characteristic, and a discharging degradation characteristic of the secondary battery; and
a degradation state analysis unit that estimates a storage degradation amount, a charging degradation amount, and a discharging degradation amount of the secondary battery on the basis of the specified degradation characteristic information and the usage data of the secondary battery,
wherein the degradation state analysis unit performs:
estimating a storage degradation amount of the secondary battery on the basis of the specified storage degradation characteristic and state of charge (SOC), temperature, and elapsed time obtained based on the usage data of the secondary battery;
estimating a charging degradation amount of the secondary battery on the basis of SOC, a charging rate, temperature, and a charging amount obtained based on the specified charging degradation characteristic and the usage data of the secondary battery; and
estimating a discharging degradation amount of the secondary battery on the basis of SOC, a discharging rate, temperature, and a discharging amount obtained based on the specified discharging degradation characteristic and the usage data of the secondary battery.

2. The degradation state estimation system according to claim 1, further comprising:
an SOH estimation unit that adds up the storage degradation amount, the charging degradation amount, and the discharging degradation amount of the secondary battery estimated by the degradation state analysis unit so as to estimate the state of health (SOH) of the secondary battery.

3. The degradation state estimation system according to claim 2,
wherein the SOH estimation unit performs:
correcting the estimated storage degradation amount of the secondary battery using SOH obtained at the time of storage of the secondary battery;
correcting the estimated charging degradation amount of the secondary battery using the depth of discharge (DOD) for an amount that has changed due to the current charging cycle of the secondary battery;
correcting the estimated discharging degradation amount of the secondary battery using the DOD for an amount that has changed due to the current discharging cycle of the secondary battery; and
adding up the estimated storage degradation amount of the secondary battery, the estimated charging degradation amount of the secondary battery, and the estimated discharging degradation amount of the secondary battery.

4. The degradation state estimation system according to claim 1,
wherein the degradation state analysis unit calculates the amount of increase in the storage degradation amount of the secondary battery each time a predetermined time elapses or each time the temperature of the secondary battery changes by a predetermined temperature, adds the amount of increase to the previously calculated storage deterioration amount of the secondary battery, and updates the storage deterioration amount of the secondary battery.

5. The degradation state estimation system according to claim 1,
wherein the degradation state analysis unit calculates the amount of increase in the charging degradation amount or discharging degradation amount of the secondary battery each time a predetermined time elapses or each time the SOC of the secondary battery changes by a predetermined value, adds the amount of increase to the previously calculated charging degradation amount or discharging degradation amount of the secondary battery, and updates the charging degradation amount or discharging degradation amount of the secondary battery.

6. The degradation state estimation system according to claim 1, further comprising:
a degradation cause specifying unit that specifies a main cause of the degradation of the secondary battery based on a breakdown of the storage degradation amount, the charging degradation amount, and the discharging degradation amount estimated by the degradation state analysis unit; and
a comment generation unit that generates a comment on how to use the secondary battery to be presented to the user based on the specified main cause of the degradation of the secondary battery.

7. A degradation state estimation method comprising:
acquiring usage data of a secondary battery and battery information for specifying the type of the secondary battery;
searching a degradation characteristic database on the basis of the battery information and specifying degradation characteristic information that includes a storage degradation characteristic, a charging degradation characteristic, and a discharging degradation characteristic of the secondary battery;
estimating a storage degradation amount, a charging degradation amount, and a discharging degradation amount of the secondary battery on the basis of the specified degradation characteristic information and the usage data of the secondary battery;
wherein the estimating includes:
estimating a storage degradation amount of the secondary battery on the basis of the specified storage degradation characteristic and SOC, temperature, and elapsed time obtained based on the usage data of the secondary battery;
estimating a charging degradation amount of the secondary battery on the basis of SOC, a charging rate, temperature, and a charging amount obtained based on the specified charging degradation characteristic and the usage data of the secondary battery; and
estimating a discharging degradation amount of the secondary battery on the basis of SOC, a discharging rate, temperature, and a discharging amount obtained based on the specified discharging degradation characteristic and the usage data of the secondary battery.

8. A non-transitory computer-readable recording medium having embodied thereon a degradation state estimation program including computer-implemented modules comprising:
a module that acquires usage data of a secondary battery and battery information for specifying the type of the secondary battery;
a module that searches a degradation characteristic database on the basis of the battery information and specifies degradation characteristic information that includes a storage degradation characteristic, a charging degradation characteristic, and a discharging degradation characteristic of the secondary battery; and
a module that estimates a storage degradation amount, a charging degradation amount, and a discharging degradation amount of the secondary battery on the basis of the specified degradation characteristic information and the usage data of the secondary battery,
wherein the module that estimates the storage degradation amount includes:
estimating a storage degradation amount of the secondary battery on the basis of the specified storage degradation characteristic and SOC, temperature, and elapsed time obtained based on the usage data of the secondary battery;
estimating a charging degradation amount of the secondary battery on the basis of SOC, a charging rate, temperature, and a charging amount obtained based on the specified charging degradation characteristic and the usage data of the secondary battery; and
estimating a discharging degradation amount of the secondary battery on the basis of SOC, a discharging rate, temperature, and a discharging amount obtained based on the specified discharging degradation characteristic and the usage data of the secondary battery.
